(19) United States
(12) Patent Application Publication
(10) Pub. No.: US 2009/0311427 A1
(43) Pub. Date: Dec. 17, 2009

(54) Mask Dimensional Adjustment and Positioning System and Method

(75) Inventors: Joseph A. Marcanio, Greensburg, PA (US); Roger Stewart, Hillsborough, NJ (US)

Correspondence Address: THE WEBB LAW FIRM, P.C., 700 KOPPERS BUILDING, 436 SEVENTH AVENUE, PITTSBURGH, PA, 15219, US

(73) Assignee: ADVANTECH GLOBAL, LTD, Tortola (VG)

(21) Appl. No.: 12/483,430

(22) Filed: Jun. 12, 2009

Related U.S. Application Data
(60) Provisional application No. 61/061,271, filed on Jun. 13, 2008.

(51) Int. Cl. B05D 1/32; C23C 14/00; H05K 3/00

(52) U.S. Cl. 427/282; 118/50; 29/829

(57) ABSTRACT

In a system and method of dimensional adjustment or positioning of an aperture mask for depositing a pattern of material on a substrate, an aperture mask is coupled to a frame such that the frame does not block one or more deposition apertures of the aperture mask. An external force applied to the frame causes the frame to move or bend and place the aperture mask in tension or compression thereby adjusting at least one dimension of the aperture mask or a position of at least one deposition aperture.

### CROSS REFERENCE TO RELATED APPLICATIONS

The present invention claims priority from U.S. Provisional Patent Application No. 61/061,271, filed on Jun. 13, 2008, entitled Mask Dimensional Adjustment and Positioning System and Method, which is incorporated herein by reference.

### BACKGROUND OF THE INVENTION

1. Field of the Invention

The present invention relates to aperture masks for depositing materials on substrates and, more particularly, to a method using aperture masks that enables the aperture masks to have desired dimensions during deposition.

2. Description of Related Art

An aperture mask, also known as a shadow mask, is a device that is typically used for depositing a desired pattern of material on a substrate. An aperture mask can be utilized for depositing a thin film pattern of material on a substrate in the presence of and in a vacuum deposition chamber via a vapor deposition process known in the art or can be utilized for depositing a thick film pattern of material, such as a solder paste, on a substrate in a screen printing process known in the art.

Desirably, an aperture mask is made with very tight control of its dimensional tolerance to ensure that its features, e.g., apertures, have the correct size and/or position required. In addition, the aperture mask is desirably flat to ensure intimate contact with the substrate on which the material pattern is being formed to avoid underspray. The aperture mask is also desirably thermally stable, whereupon it does not change dimensional tolerance or flatness at deposition temperature. Lastly, the thickness of the aperture mask is desirably small to allow minimal feature size and minimal deposition shadowing.

Aperture masks with very fine features are typically electroformed rather than etched in order to produce apertures that are not only small, but with small distance between them. In this process, structures, i.e., apertures, are created by selectively electroplating metal onto a conductive mandrel, which has been patterned with areas of non-conductive photoresist. The patterned electroplated material, or aperture mask, is later removed from the mandrel. Resolution of the aperture mask is therefore only limited by the resolution capability of the non-conductive photoresist.

In the electroforming process, photoresist can be patterned onto the mandrel with suitable accuracy and precision. However, the electroplated metal typically exhibits some degree of stress, either compressive or tensile, depending on plating conditions. When removed from the mandrel, the internal stress will cause the aperture mask to expand (compressive) or contract (tensile), resulting in dimensional errors of feature position. Thus, fabricating a shadow mask with extreme accuracy of feature positions by electroforming is difficult and expensive, if not impossible for increasing resolution and overall area.

To perform vapor deposition through an aperture mask, the aperture mask must be held flat and in intimate contact with the substrate in order to avoid evaporated material deposited via one or more apertures in the aperture mask from seeping behind the mask onto the substrate in unintended area(s) adjacent each aperture. To achieve this, the thin aperture mask is commonly bonded to a rigid frame by one of various well-known methods and is often mounted under tension in one dimension, dV (vertically), or dH (horizontally), or two dimensions dV and dH, to assure flatness.

Problems that may be encountered after the mask is mounted on the frame include, without limitation: the mask may exhibit runout such that the dV and/or dH dimensions are either too large or too small; the mask may exhibit non-uniformity in runout of the dV and/or dH dimensions; or the mask may exhibit non-orthogonality.

During deposition, as the mask temperature increases due to the deposition process, these problems, and others, may occur, which may not have been present in the mask at room temperature. Accordingly, positioning of the mask during deposition may be difficult given the foregoing problems because position cannot remedy the problems and because the mask dimensions may be constantly changing.

What is, therefore, needed is a system and method which can correct for mask runout, runout non-uniformity, and non-orthogonality and which can make these corrections dynamically as deposition proceeds, and assure proper mask position at the same time.

### SUMMARY OF THE INVENTION

The invention is a method of dimensional adjustment or positioning of an aperture mask for depositing a pattern of material on a substrate. The method includes (a) providing an aperture mask having one or more deposition apertures for depositing a pattern of material on a substrate; (b) coupling the aperture mask to a frame whereupon the frame does not block the one or more deposition apertures; and (c) applying to the frame an external force that causes the frame to bend and place the aperture mask in tension or compression thereby adjusting at least one dimension of the aperture mask or a position of at least one deposition aperture.

The method can further include positioning the frame mounted aperture mask in operative relation to the substrate for depositing material on the substrate via the one or more deposition apertures.

Step (c) can be performed during deposition of the material on the substrate via the one or more deposition apertures.

The aperture mask can be coupled to the frame at or adjacent a periphery of the frame. The frame can have at least one corner where the aperture mask is not coupled to the frame.

The frame can be square or rectangular.

The method can further include detecting a position of one or more positioning apertures in the aperture mask; and controlling an amount of the external force applied to the frame based on the detected position of the one or more positioning apertures.

Step (c) can include applying a plurality of external forces to different portions or points of the frame.

The invention is also a system of dimensional adjustment or positioning of an aperture mask for depositing a pattern of material on a substrate. The system includes a frame coupled to an aperture mask having one or more deposition apertures for depositing a pattern of material on a substrate; and means for applying to each of one or more points or portions of the frame an external force that causes the aperture mask to be placed in tension or compression thereby adjusting at least one dimension of the aperture mask or a position of at least one deposition aperture.

The system can further include means for detecting a position of each of one or more positioning apertures in the aperture mask; and means for controlling an amount of force applied to each point or portion of the frame based on the position of each of the one or more positioning apertures detected by the means for detecting.

The means for applying can include a position actuator operative under the control of the means for controlling the amount of force applied to one of the points or portions of the frame based on an output of the means for detecting.

The force applied to the one point or portion of the frame can be applied via a lever having a first end in contact with the point or portion of the frame and a second end in contact with the position actuator.

The means for detecting can include a light source and a light detector on opposite sides of at least one of the positioning apertures; and the light detector can coupled to the means for detecting.

The frame can have at least one corner where the aperture mask is not coupled to the frame.

The aperture mask can have a cutout adjacent the at least one corner of the frame.

The aperture mask can have a first coefficient of thermal expansion while the frame can have a second, lower coefficient of thermal expansion. The aperture mask can be coupled to the frame under tension at a temperature below a temperature the aperture mask experiences during deposition of material on the substrate.

The system can further include a vacuum deposition vessel for supporting the frame mounted aperture mask in operative relation between the substrate and a material deposition source during deposition of material from ______ material deposition source onto the substrate via the one or more deposition apertures in the presence of a vacuum in the vacuum deposition vessel.

### BRIEF DESCRIPTION OF THE DRAWINGS

FIG. 1A is a top view of a shadow mask frame;

FIG. 1B is a section taken along lines IB-IB in FIG. 1A;

FIG. 2A is a top view of a shadow mask;

FIG. 2B is a section taken along lines IIB-IIB in FIG. 2A;

FIG. 3A is a top view of the shadow mask of FIG. 2A mounted to the shadow mask frame of FIG. 1A;

FIG. 3B is a section taken along lines IIIB-IIIB in FIG. 3A;

FIG. 4 is a schematic view of an exemplary vacuum deposition vessel having in the interior thereof the frame mounted shadow mask of FIG. 3A disposed in operative relation between a deposition substrate and a material deposition source which acts as a supply of material to be deposited on the substrate via apertures in the shadow mask;

FIG. 5 is a side schematic view of a dimensional adjustment and positioning system in operative relation to the frame mounted shadow mask of FIG. 3A;

FIG. 6A is a top view of the dimensional adjustment and positioning system of FIG. 5 including position detectors, position actuators, and a frame;

FIG. 6B is a section taken along lines VIB-VIB in FIG. 6A;

FIG. 7A is a top view of the dimensional adjustment and positioning system of FIG. 6A having frame 4 mounted shadow mask 2 positioned in operative relation thereon;

FIG. 7B is a section taken along lines VIIB-VIIB in FIG. 7A;

FIG. 8A is an enlarged, isolated top view of a lever of the dimensional adjustment and positioning system of FIG. 7A in operative relation to a side 5 of frame 4;

FIG. 8B is a section taken along lines VIIIB-VIIIB in FIG. 8A; and

FIG. 9 is a flow chart of a mask dimensional adjustment and positioning system method in accordance with the present invention.

### DESCRIPTION OF THE INVENTION

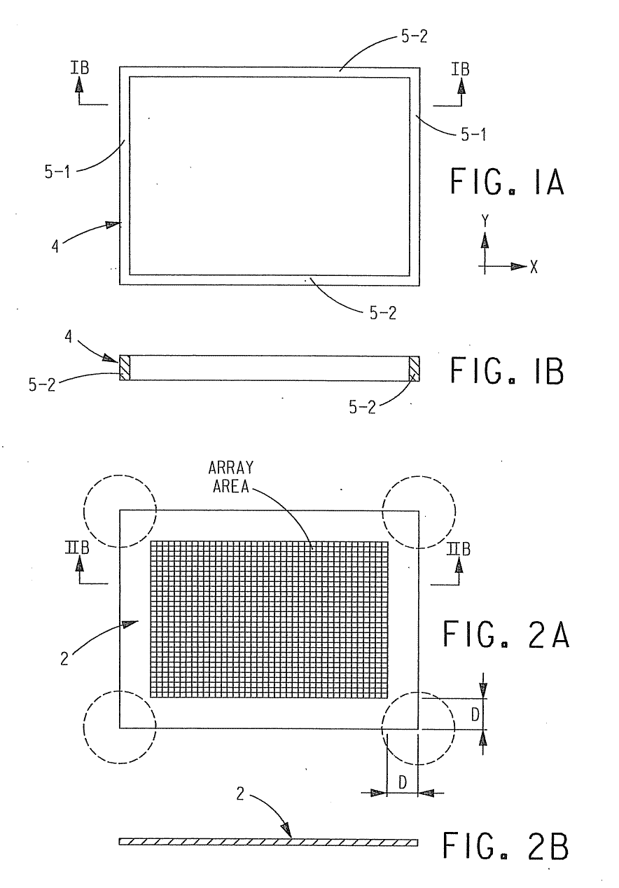

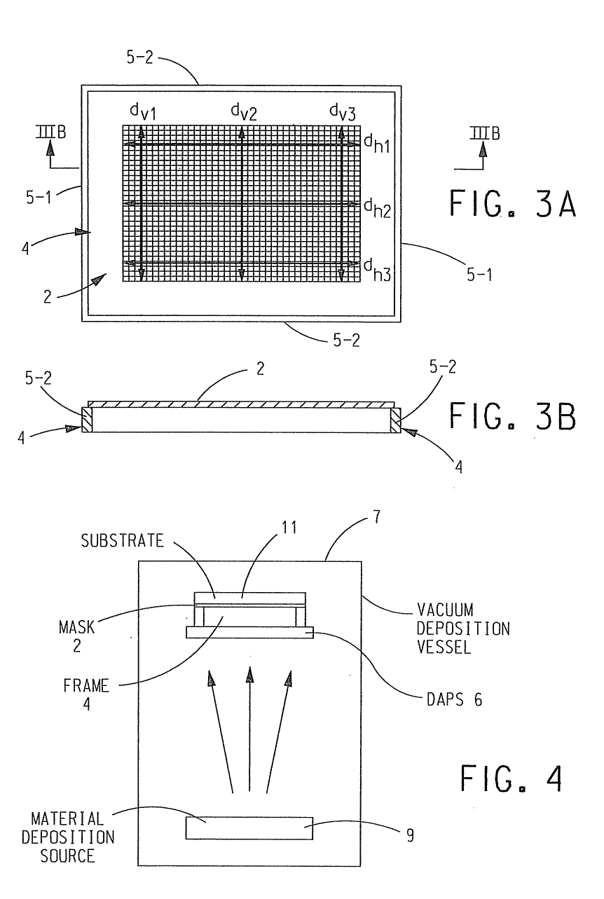

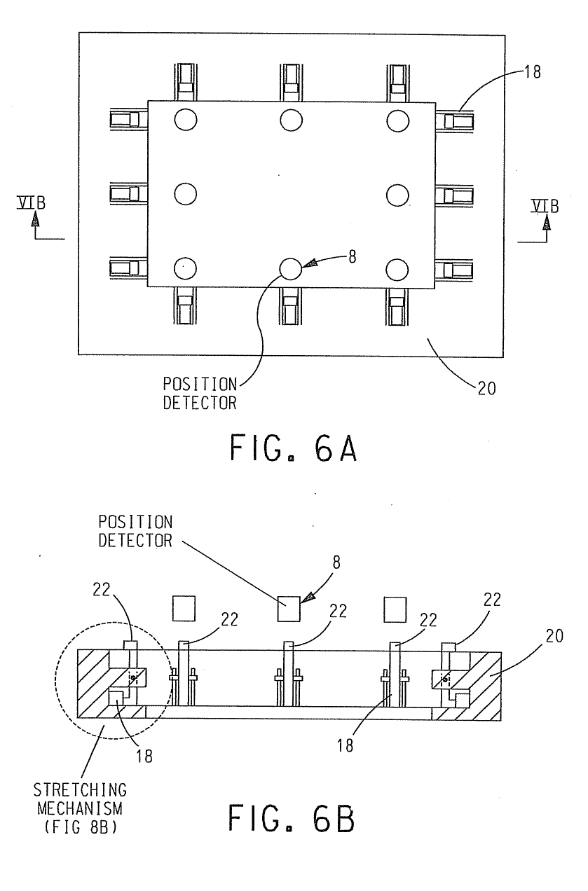

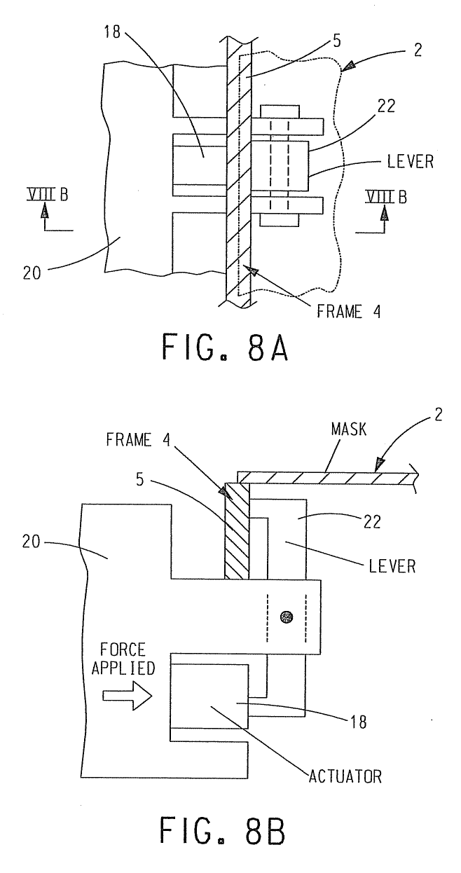

The present invention will be described with reference to the accompanying FIGS. 1-9 where like references correspond to like elements.

With reference to FIGS. 1-4, a shadow mask 2 is mounted on a frame 4. Frame 4 may be of various configurations, materials and dimensions, with square corners, rounded corners, etc. Side members 5-1 and 5-2 of frame 4 are operative for flexing in the x (dH), y (dV) directions, respectively, planar to mask 2. The materials and dimensional design of frame 4 can vary appropriate to the material forming mask 2 and process requirements. In one non-limiting embodiment, mask 2 and frame 4 can both be made from the same suitable material, such as, without limitation, Invar® or Kovar®.

Mask 2 may be applied (secured or coupled) to frame 4 by way of thermal tensioning, mechanical tensioning, or without tension, depending on the application, by welding, brazing, adhesive, or other means. In the embodiment shown in FIGS. 1-4, mask 2 and frame 4 have the same outline, e.g., rectangular, and mask 2 is secured at or adjacent its entire periphery, including its corners, to the side 5 of frame 4. However, this is not to be construed as limiting the invention since, for reasons discussed hereinafter, the corners of mask 2 and some distance D along each side 5 of mask 2 that extends away from a corner of mask 2 can be left unsecured to sides 5 of frame 4 while the remainder of mask 2 adjacent its periphery can be secured to the frame.

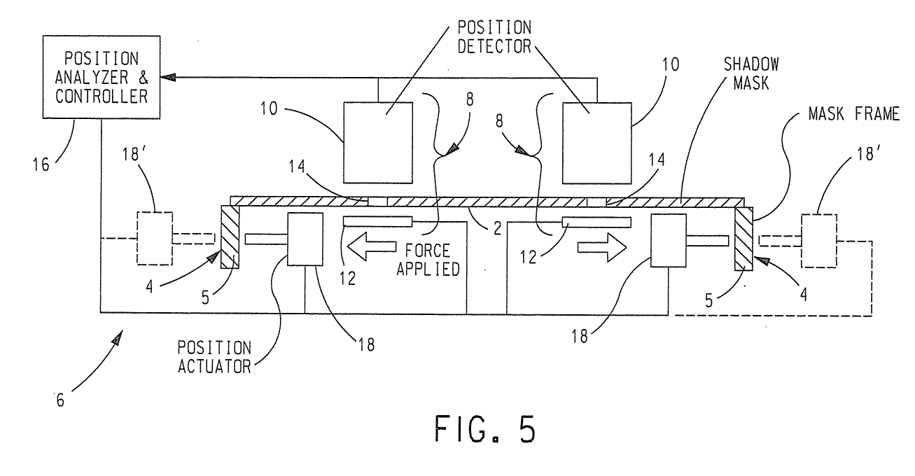

With reference to FIGS. 5-8 and with continuing reference to FIGS. 1-4, an adjusting means, also known as a dimensional adjustment and positioning system (DAPS) 6, can apply tension (or compression) to frame 4 and, hence, to mask 2 secured thereto. The assembly comprising mask 2 mounted to frame 4 can be mounted in operative relation to DAPS 6 within a vacuum deposition vessel 7 (shown generally in FIG. 4) of the type generally disclosed in U.S. Pat. No. 6,943,066, which is incorporated herein by reference.

In one exemplary embodiment shown in FIG. 4, mask 2 mounted to frame 4, which is secured to DAPS 6, is disposed between a material deposition source 9 and a substrate 11 inside of a vacuum deposition vessel 7 during the deposition of material from material deposition source 9 onto substrate 11 via apertures in mask 2 in the presence of a vacuum inside vessel 7.

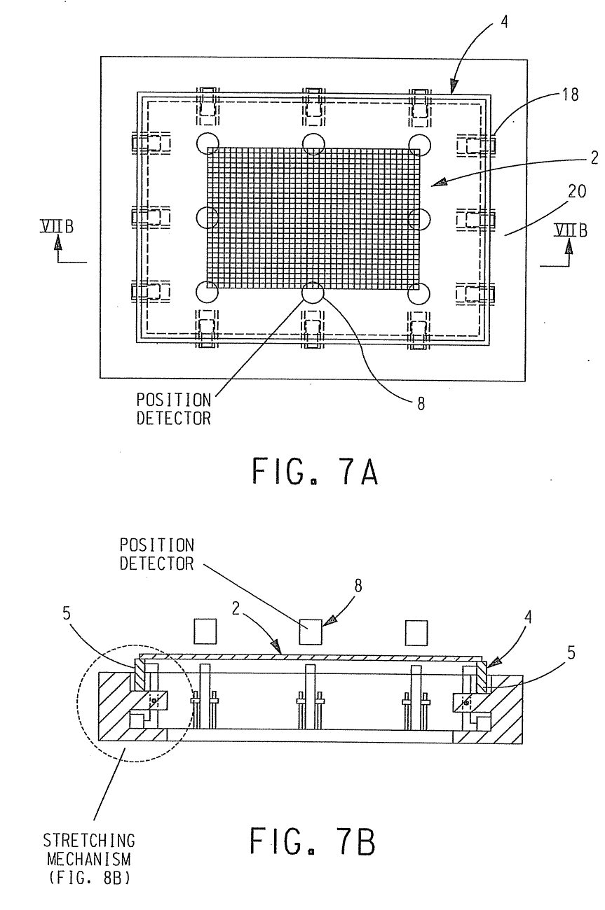

When mounted in operative relation to DAPS 6, the position of mask 2 at one or more critical or representative locations is desirably optically measured by position detectors 8 of DAPS 6. In one exemplary embodiment, each detector 8 includes one or more light sources 12 and one or more light detectors 10 on opposite sides of one or more positioning apertures 14 in mask 2. The output of each light detector 10 is fed to a position analyzer and controller 16. Based on the output of one or more light detectors 10 in response to detecting light output by one or more light sources 12 after passage through one or more apertures 14, controller 16 computes appropriate adjustment(s) to be applied to the sides 5 of frame 4 and sends signals to one or more position actuators 18 which, either directly or indirectly via suitable mechanical means, such as a lever 22 shown best in FIG. 7, apply force(s) to one or more sides of frame 4 thereby maneuvering mask 2 by selectively bending one or more sides 5 of frame 4, thereby correcting runout, orthogonality, and position errors in mask 2. The number of position detectors 8 and position actuators 18 as well as their position can vary dependent on need.

While position actuators 18 illustrated in FIGS. 5-8 are disposed to apply outwardly directed force(s) to the interior of frame 4 to place mask 2 in tension, it is envisioned that position actuators 18′ (shown in phantom in FIG. 4) can also or alternatively be provided for applying inwardly directed force(s) to one or more sides 5 of frame 4 to place mask 2 under compression.

Using this system, mask dimensional errors can be corrected dynamically. Also, DAPS 6 eliminates the need for expensive, complex, and bulky X-Y-Theta stage translation for mask positioning.

A possible problem with using DAPS 6 to selectively bend frame 4 and, hence, adjust the runout, orthogonality, and position (dimensions) of mask 2 occurs at the corners of frame 4 where the horizontal and vertical sides 5 of frame 4 meet and prevent vertical and horizontal movement of each other. To avoid this problem, mask 2, formed from a first material having a first coefficient of thermal expansion (CTE), can be mounted to frame 4, formed from a second material having a lower CTE than the CTE of the material forming mask 2, under tension at deposition temperature and below in the manner disclosed in International Application No. PCT/US2006/042858 which is incorporated herein by reference. By way of DAPS 6 in combination with mask 2 mounted to frame 4 under tension, the need for the horizontal and vertical sides 5 of frame 4 to move adjacent the corners thereof can be avoided or eliminated.

Also or alternatively, frame 4 can be made sufficiently larger than the area of the mask used for deposition, whereupon the effect of the horizontal and vertical sides 5 of frame 4 inability to move adjacent the corners of frame 4 does not affect the ability of DAPS 6 to bend frame 4 away from the corners of mask 2 in the manner described above thereby suitably adjusting the mask dimensions in a deposition region of mask 2.

Also or alternatively, as discussed above, mask 2 at and adjacent its corners can be left unsecured to frame 4 for a distance D along each side of mask 2 that extends away from each corner of mask 2. Also or alternatively, the portions of mask 2 adjacent each corner thereof shown in dashed circles in FIG. 2 can be eliminated or cut out, whereupon only the lengths of mask 2 that extend along the sides thereof between the eliminated corner portions are secured adjacent the periphery of mask 2 to the frame 4.

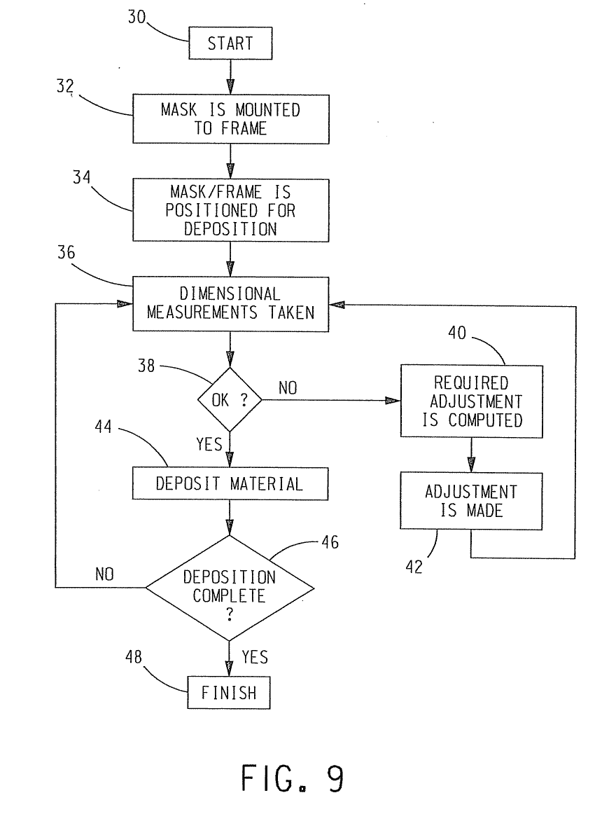

With reference to FIG. 9, and with continuing reference to all previous figures, a method of mask dimensional adjustment and positioning commences by advancing from a start step 30 to a step 32 where a mask 2 is mounted to a frame 4. The method then advances to step 34 wherein the mask mounted frame is mounted on DAPS 6 and is positioned in a vacuum deposition vessel between a substrate upon which material is to be deposited and a material deposition source in the presence of a vacuum. At step 36, DAPS 6 takes dimensional measurements of mask 2 in the deposition chamber. At step 38, controller 16 of DAPS 6 determines if mask 2 requires adjustment to correct for dimensional errors, such as, without limitation, runout, runout non-uniformity, non-orthogonality, and the like.

If adjustment is required, the method advances to step 40 wherein controller 16 computes the adjustment required. Thereafter suitable position actuators 18, 18′ positioned along one or more sides 5 of frame 4 are controlled under the control of controller 16 to adjust the position of said one or more sides 5 of frame 4.

Steps 36-42 are repeated as necessary until in one iteration of step 38 it is determined that the dimensions of mask 2 are set suitably for vapor depositing material released from the material deposition source on the substrate via one or more apertures in mask 2 in the presence of a vacuum inside the deposition vacuum vessel. Upon making this decision in an iteration of step 38, the method advances to step 44 where the deposition of material on the substrate commences.

At step 48, a decision is made whether the deposition event is complete. If not, steps 36, 38, 44, and 46 are repeated as necessary until in one iteration of step 46 it is determined that the deposition event is complete, whereupon the method advances to finish step 48. If, in any iteration of step 38 during the deposition event, it is determined that the dimensional measurements of mask 2 require adjustment, steps 40 and 42 are executed to adjust the dimensions of mask 2 during the deposition event. Hence, not only are the dimensions of mask 2 adjusted prior to commencing the deposition event, but the dimensions of mask 2 are checked and adjusted as necessary during the deposition event in order to improve the accuracy of the deposition of material on the substrate, while avoiding mask runout, runout non-uniformity, and non-orthogonality that ordinarily occurs as the temperature of mask 2 changes during the deposition event.

The invention has been described with reference to the preferred embodiment. Obvious modifications and alterations will occur to those skilled in the art upon reading and understanding the preceding detailed description. It is intended that the invention be construed as including all such modifications and alterations insofar as they come within the scope of the appended claims or the equivalence thereof.

The invention claimed is:

1. A method of dimensional adjustment or positioning of an aperture mask for depositing a pattern of material on a substrate, the method comprising:
(a) providing an aperture mask having one or more deposition apertures for depositing a pattern of material on a substrate;
(b) coupling the aperture mask to a frame whereupon the frame does not block the one or more deposition apertures; and
(c) applying to the frame an external force that causes the frame to bend and place the aperture mask in tension or compression thereby adjusting at least one dimension of the aperture mask or a position of at least one deposition aperture.

2. The method of claim 1, further including positioning the frame mounted aperture mask in operative relation to the substrate for depositing material on the substrate via the one or more deposition apertures.

3. The method of claim 2, wherein step (c) is performed during deposition of the material on the substrate via the one or more deposition apertures.

4. The method of claim 1, wherein the aperture mask is coupled to the frame at or adjacent a periphery of the frame.

5. The method of claim 1, wherein:
the frame has at least one corner; and
the aperture mask is not coupled to the frame at said corner.

6. The method of claim 1, wherein the frame is square or rectangular.

7. The method of claim 1, further including:
detecting a position of one or more positioning apertures in the aperture mask; and
controlling an amount of the external force applied to the frame based on the detected position of the one or more positioning apertures.

8. The method of claim 1, wherein step (c) includes applying a plurality of external forces to different portions or points of the frame.

9. A system of dimensional adjustment or positioning of an aperture mask for depositing a pattern of material on a substrate, the system comprising:
a frame coupled to an aperture mask having one or more deposition apertures for depositing a pattern of material on a substrate; and
means for applying to each of one or more points or portions of the frame an external force that causes the aperture mask to be placed in tension or compression thereby adjusting at least one dimension of the aperture mask or a position of at least one deposition aperture.

10. The system of claim 9, further including:
means for detecting a position of each of one or more positioning apertures in the aperture mask; and
means for controlling an amount of force applied to each point or portion of the frame based on the position of each of the one or more positioning apertures detected by the means for detecting.

11. The system of claim 10, wherein the means for applying includes a position actuator operative under the control of the means for controlling the amount of force applied to one of the points or portions of the frame based on an output of the means for detecting.

12. The system of claim 11, wherein the force applied to the one point or portion of the frame is applied via a lever having a first end in contact with the point or portion of the frame and a second end in contact with the position actuator.

13. The system of claim 10, wherein:
the means for detecting includes a light source and a light detector on opposite sides of at least one of the positioning apertures; and
the light detector is coupled to the means for detecting.

14. The system of claim 9, wherein;
the frame has at least one corner; and
the aperture mask is not coupled to the frame at or adjacent the at least one corner of the frame.

15. The system of claim 14, wherein the aperture mask has a cutout adjacent the at least one corner of the frame.

16. The system of claim 9, wherein:
the aperture mask has a first coefficient of thermal expansion;
the frame has a second, lower coefficient of thermal expansion; and
the aperture mask is coupled to the frame under tension at a temperature below a temperature the aperture mask experiences during deposition of material on the substrate.

17. The system of claim 9, further including a vacuum deposition vessel for supporting the frame mounted aperture mask in operative relation between the substrate and a material deposition source during deposition of material from material deposition source onto the substrate via the one or more deposition apertures in the presence of a vacuum in the vacuum deposition vessel.
